(19) United States
(12) Patent Application Publication
(10) Pub. No.: US 2026/0280504 A1
(43) Pub. Date: Sep. 17, 2026

(54) AMPLIFIER WITH COMMON-MODE VOLTAGE SETTING CIRCUIT

(71) Applicant: Texas Instruments Incorporated, Dallas, TX (US)

(72) Inventor: Purnendu Bhattaru, Bangalore (IN)

(21) Appl. No.: 19/077,286

(22) Filed: Mar. 12, 2025

(51) Int. Cl. H03F 3/45

(52) U.S. Cl. CPC H03F 3/45475

(57) ABSTRACT

In described examples, a device includes first and second voltage sensors, first and second error amplifiers, and a fully differential amplifier (FDA). A first input of the first error amplifier (EA1) is coupled to the output of the first voltage sensor (VS1). A first input of the second error amplifier (EA2) is coupled to the output of the second voltage sensor (VS2). A first input of the FDA is coupled to a first input of VS1. A second input of the FDA is coupled to the second input of VS1. A third input of the FDA is coupled to an output of EA2. A first output of the FDA is coupled to a first input of the VS2 and an output of EA1. A second output of the FDA is coupled to a second input of the VS2 and the output of EA1.

### TECHNICAL FIELD

This application relates generally to amplifiers, and in particular to an amplifier with circuits corresponding to separate feedback loops to set different common-mode voltages.

### BACKGROUND

Differential signaling is used in contexts including audio, data transmission, telephony, and high-speed data acquisition applications. In some examples, analog-to-digital converters (ADCs) use differential inputs, and a differential amplifier is used to drive the ADC's differential inputs. In some examples, it is advantageous to maximize an input range and an output range of a differential amplifier.

### SUMMARY

In described examples, a device includes first and second voltage sensors, first and second error amplifiers, and a fully differential amplifier (FDA). A first input of the first error amplifier (EA1) is coupled to the output of the first voltage sensor (VS1). A first input of the second error amplifier (EA2) is coupled to the output of the second voltage sensor (VS2). A first input of the FDA is coupled to a first input of VS1. A second input of the FDA is coupled to the second input of VS1. A third input of the FDA is coupled to an output of EA2. A first output of the FDA is coupled to a first input of the VS2 and an output of EA1. A second output of the FDA is coupled to a second input of the VS2 and the output of EA1.

In described examples, a device includes a first common mode feedback circuit (CMFB), a second CMFB, and a fully differential amplifier. A first input of the fully differential amplifier is coupled to a first input of the first CMFB. A second input of the fully differential amplifier is coupled to a second input of the first CMFB. A third input of the fully differential amplifier is coupled to an output of the second CMFB. A first output of the fully differential amplifier is coupled to a first input of the second CMFB and an output of the first CMFB. A second output of the fully differential amplifier is coupled to a second input of the second CMFB and the output of the first CMFB.

In described examples, a device includes a first input stage, a second input stage, a first CMFB, a second CMFB, and a fully differential amplifier. An output of the first input stage is coupled to a first input of the fully differential amplifier and a first input of the first CMFB circuit. An output of the second input stage is coupled to a second input of the fully differential amplifier and a second input of the first CMFB. A third input of the fully differential amplifier is coupled to an output of the second CMFB. A first output of the fully differential amplifier is coupled to a first input of the first input stage, a first input of the second CMFB, and an output of the first CMFB circuit. A second output of the fully differential amplifier is coupled to a first input of the second input stage, a second input of the second CMFB circuit, and the output of the first CMFB circuit.

### BRIEF DESCRIPTION OF THE DRAWINGS

FIG. 1 is a functional block and circuit diagram of an example instrumentation amplifier.

FIG. 2 is a functional block diagram and circuit diagram of an example implementation of the instrumentation amplifier of FIG. 1.

FIG. 3 is another example circuit diagram of the instrumentation amplifier of FIG. 1.

FIG. 4 is a common-mode equivalent circuit diagram of the instrumentation amplifier of FIG. 1.

FIG. 5 is a circuit diagram of an instrumentation amplifier similar to the instrumentation amplifier of FIG. 3, without the first CMFB.

FIG. 6 is a graph of common-mode voltage gain against frequency for the instrumentation amplifier of FIG. 1 and for a second example instrumentation amplifier (not shown).

FIG. 7 is a graph of differential gain against frequency for the second instrumentation amplifier described with respect to FIG. 6.

FIG. 8 is a graph of differential gain against frequency for the instrumentation amplifier of FIG. 1.

FIG. 9 is a set of graphs of distortion against frequency for different distortion harmonics for the second instrumentation amplifier described with respect to FIG. 6.

FIG. 10 is a set of graphs of distortion against frequency for different distortion harmonics for the instrumentation amplifier of FIG. 1.

### DETAILED DESCRIPTION

An instrumentation amplifier is a class of differential amplifiers that has high input impedance. In some examples, high input impedance reduces or eliminates output signal quality dependency on matching input impedance to source impedance. In some examples, instrumentation amplifiers enable improved accuracy and circuit stability. Instrumentation amplifiers are used in applications including test equipment and other signal measurement systems, flow transmitters, surgical equipment, and other high precision systems.

Herein, signal swing refers to an available signal level range (such as voltage range) for a corresponding signal. In some examples, increasing available signal swing of an amplifier increases an available input and/or output signal level range of the amplifier. In some examples, plus and minus polarity voltages of an error amplifier (a differential amplifier or other error amplifier) are bounded by high and low voltage references of the device, such as a source voltage and a ground voltage, respectively. Common-mode voltages can be adjusted accordingly to increase or maximize available voltage swing of signals in an error amplifier. Corresponding plus polarity and minus polarity voltages are increased by the same common-mode voltage, so that plus polarity signals have an available voltage swing equal to an available voltage swing of corresponding minus polarity signals.

An instrumentation amplifier is described below in which separate feedback loops are used to adjust different common-mode voltages of an instrumentation amplifier. Using separate feedback loops to adjust common-mode voltages may provide one or more of various benefits. Such benefits include improved flexibility of common-mode voltage selection, independence of common-mode voltage feedback from differential gain path stability, simplified circuit optimization, and improved common-mode voltage suppression. Also, common-mode input voltage is decoupled from common-mode output voltage.

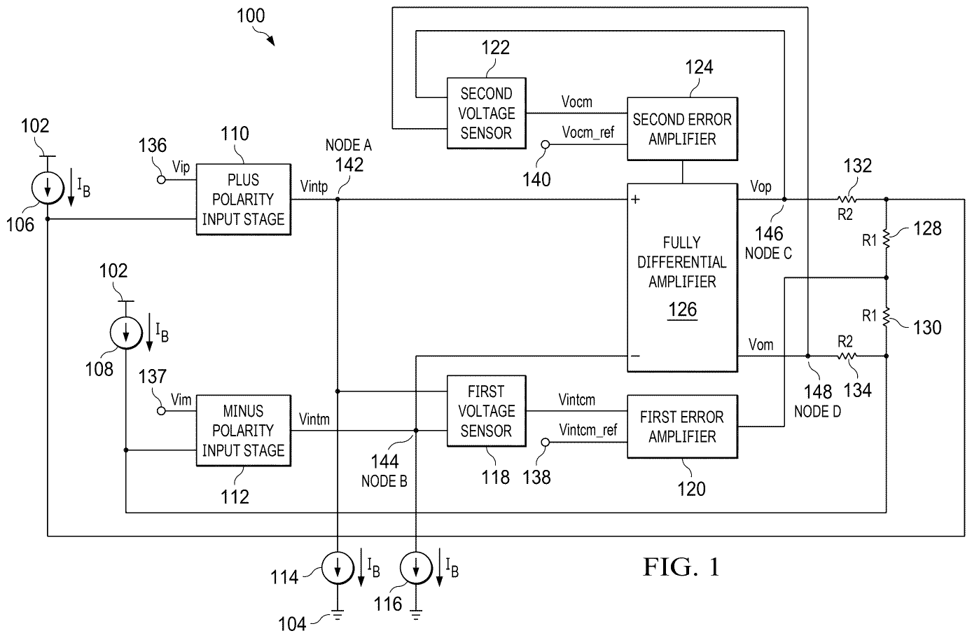

FIG. 1 is a functional block and circuit diagram of an example instrumentation amplifier 100. The instrumentation amplifier 100 includes a voltage source terminal 102 coupled to a power source, a ground terminal 104 coupled to a ground, a first current source 106, a second current source 108, a plus polarity input stage 110, a minus polarity input stage 112, a third current source 114, a fourth current source 116, a first voltage sensor 118, a first error amplifier 120, a second voltage sensor 122, a second error amplifier 124, a fully differential amplifier 126, a first resistor 128, a second resistor 130, a third resistor 132, and a fourth resistor 134. Note that error amplifiers receive a first input voltage V1 and a second input voltage V2 and have a gain A, and provide an output voltage Vout=A×(V1−V2). This output voltage may be provided by a single output, as in the first and second error amplifiers 120 and 124, or by two differential outputs, as in the fully differential amplifier 126. The same reference numbers or other reference designators are used in the drawings to designate features that are closely related structurally and/or functionally.

The first, second, third, and fourth current sources 106, 108, 114, and 116 each provide an input bias current I_{B}. The first and second resistors 128 and 130 have a resistance R1. The third and fourth resistors 132 and 134 have a resistance R2.

The voltage source terminal 102 is coupled to a first terminal of the first current source 106 and a first terminal of the second current source 108. A second terminal of the first current source 106 is coupled to a first input of the plus polarity input stage 110, a first terminal of the first resistor 128, and a first terminal of the third resistor 132. A second input of the plus polarity input stage 110 is coupled to a first input terminal 136. The first input terminal 136 receives a plus polarity input signal voltage (Vip). A second terminal of the second current source 108 is coupled to a first input of the minus polarity input stage 112, a first terminal of the second resistor 130, and a first terminal of the fourth resistor 134. A second input of the minus polarity input stage 112 is coupled to a second input terminal 137. The second input terminal 137 receives a minus polarity input signal voltage (Vim).

An output of the plus polarity input stage 110 is coupled to a non-inverting input (a first input) of the fully differential amplifier 126, a first input of the first voltage sensor 118, and a first terminal of the third current source 114. A voltage at the output of the plus polarity input stage 110 is an intermediate plus polarity voltage (Vintp). A second terminal of the third current source 114 is coupled to the ground terminal 104. An output of the minus polarity input stage 112 is coupled to an inverting input (a second input) of the fully differential amplifier 126, a second input of the first voltage sensor 118, and a first terminal of the fourth current source 116. A voltage at the output of the minus polarity input stage 112 is an intermediate minus polarity voltage (Vintm). A second terminal of the fourth current source 116 is coupled to the ground terminal 104.

An output of the first voltage sensor 118, shown as an intermediate common-mode voltage (Vintcm), is coupled to a first input of the first error amplifier 120. Vintcm can be described as a common-mode voltage enabling improved signal swing for the non-inverting and inverting inputs of the fully differential amplifier 126. A second input of the first error amplifier 120 is coupled to a third input terminal 138. The third input terminal 138 receives an intermediate common-mode reference voltage (Vintem_ref). The first error amplifier 120 sets Vintcm to Vintcm_ref using negative feedback. An output of the first error amplifier 120 is coupled to a second terminal of the first resistor 128 and a second terminal of the second resistor 130.

A first output of the fully differential amplifier 126 is coupled to a second terminal of the third resistor 132 and a first input of the second voltage sensor 122. The first output of the fully differential amplifier 126 provides a plus polarity output voltage Vop. A second output of the fully differential amplifier 126 is coupled to a second terminal of the fourth resistor 134 and a second input of the second voltage sensor 122. The second output of the fully differential amplifier 126 provides a minus polarity output voltage Vom.

An output of the second voltage sensor 122 is coupled to a first input of the second error amplifier 124. A second input of the second error amplifier 124 is coupled to a fourth input terminal 140. The fourth input terminal receives an output common-mode voltage reference (Vocm_ref). An output common-mode voltage (Vocm) can be described as a common-mode voltage enabling improved signal swing for the differential outputs (Vop and Vom) of the fully differential amplifier 126. An output of the second error amplifier 124 is coupled to a third input of the fully differential amplifier 126.

The first (non-inverting) and second (inverting) inputs of the fully differential amplifier 126 are differential inputs that receive Vintp and Vintm, respectively. As described above, Vop and Vom are differential outputs, so that a difference between Vop and Vom (accordingly, Vop minus Vom) may be described as the output of the fully differential amplifier 126. In some examples, the fully differential amplifier 126 determines the difference between Vop and Vom responsive to a difference between Vintp and Vintm and a gain of the fully differential amplifier 126. The fully differential amplifier 126 determines Vocm responsive to the feedback signal provided by the second error amplifier 124.

Vip equals the sum of a plus polarity data signal (Vdp, not shown) and a common-mode input voltage (Vicm). Vim equals the sum of a minus polarity data signal (Vdm, not shown) and Vicm.

There is a node A 142 between the output of the plus polarity input stage 110 and the non-inverting input of the fully differential amplifier 126. A voltage at node A 142 is Vintp. Vintp equals the sum of Vintem and a plus polarity intermediate data signal voltage Vintdp (not shown) that is responsive to Vdp. There is a node B 144 between the output of the minus polarity input stage 112 and the inverting input of the fully differential amplifier 126. A voltage at node B 144 is Vintm. Vintm equals the sum of Vintcm and a minus polarity intermediate data signal voltage Vintdm (not shown) that is responsive to Vdm.

The first voltage sensor 118 senses Vintcm responsive to Vintp and Vintm. In an example, the first voltage sensor 118 determines the average of Vintp and Vintm. Note that (Vintp+Vintm)/2=(Vintdp+Vintcm+Vintdm+Vintcm)/2=Vintcm. The first error amplifier 120 provides a first feedback current responsive to a difference between the output (Vintcm) of the first voltage sensor 118 and Vintcm_ref. The first error amplifier 120 provides the first feedback current to a node between the first resistor 128 and the second resistor 130 to enable a feedback loop to control Vintem to equal Vintcm_ref. In an example, the first feedback current equals zero if Vintem equals Vintcm_ref.

There is a node C 146 between the first output of the fully differential amplifier 126 and the second terminal of the third resistor 132. A voltage at node C 146 is a plus polarity output voltage (Vop). Vop equals the sum of Vocm and a plus polarity output data signal voltage (Vodp). Vodp is responsive to a difference between Vintp and Vintm (equivalently, between Vintdp and Vintdm, because Vintcm is canceled out), and to a gain (A_{FDA}) of the fully differential amplifier 126. There is a node D 148 between the second output of the fully differential amplifier 126 and the second terminal of the fourth resistor 134. A voltage at node D 148 is a minus polarity output voltage (Vom). Vom equals the sum of Vocm and a minus polarity output data signal voltage (Vodm). Vodm is responsive to A_{FDA} and a difference between Vintdp and Vintdm. The voltages at nodes C and D 146 and 148 are each responsive to a difference between Vintdp and Vintdm. Accordingly, Vintem is partially or entirely canceled out and has little or no effect on the voltages at nodes C and D 146 and 148.

In an example, Vop equals Vocm+A_{FDA}×(Vintp−Vintm)/2, and Vom equals Vocm−A_{FDA}×(Vintp−Vintm)/2. The gain of the instrumentation amplifier 100 is set by R1 and R2, so that gain=(Vop−Vom)/(Vip−Vim)=1+ (R2/R1).

The second voltage sensor 122 senses Vocm responsive to Vop and Vom. In an example, the second voltage sensor 122 determines the average of Vop and Vom. Note that Vop and Vom are symmetric around Vocm, so that (Vop+Vom)/2=(Vop+Vocm+Vom+Vocm)/2=Vocm. The second error amplifier 124 provides a second feedback current responsive to a difference between the output (Vocm) of the second voltage sensor 122 and Vocm_ref. The second error amplifier 124 provides the second feedback current to the third input of the fully differential amplifier 122. This enables a feedback loop to control Vocm to equal Vocm_ref. In an example, the second feedback current equals zero if Vocm equals Vocm_ref.

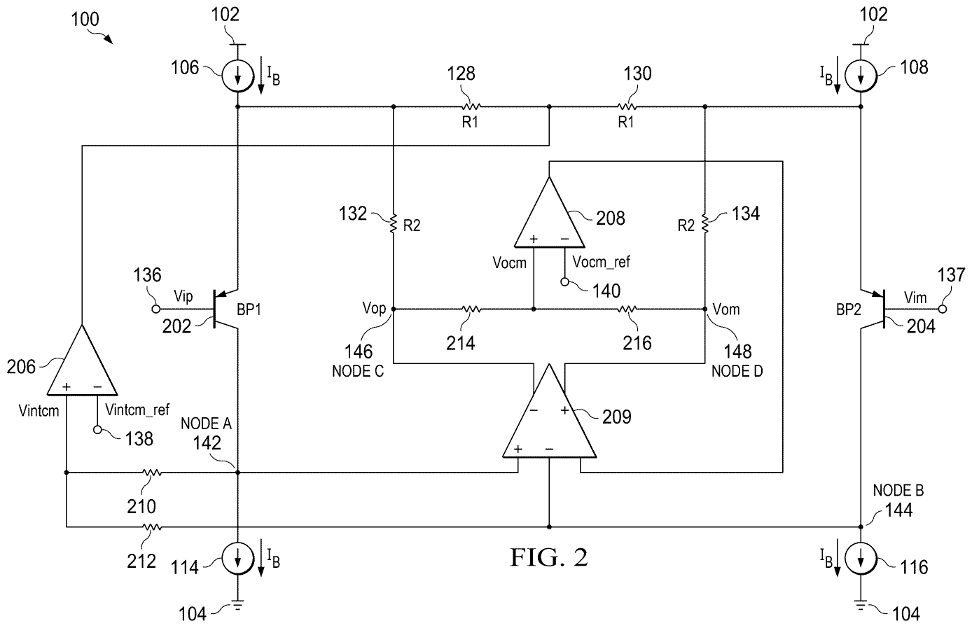

FIG. 2 is an example circuit diagram of the instrumentation amplifier 100 of FIG. 1. The instrumentation amplifier 100 includes a first pnp-type bipolar junction transistor (BJT) (BP1) 202, a second pnp-type BJT (BP2) 204, a first error amplifier 206, a second error amplifier 208, a fully differential amplifier 209, a fifth resistor 210, a sixth resistor 212, a seventh resistor 214, and an eighth resistor 216.

In an example, BP1 202 corresponds to the plus polarity input stage 110 of FIG. 1. BP2 204 corresponds to the minus polarity input stage 112. The first error amplifier 206 corresponds to the first error amplifier 120. The second error amplifier 208 corresponds to the second error amplifier 124. The fully differential amplifier 209 corresponds to the fully differential amplifier 126. The fifth and sixth resistors 210 and 212 together correspond to the first voltage sensor 118. And the seventh and eighth resistors 214 and 216 together correspond to the second voltage sensor 122.

A base of BP1 202 is coupled to the first terminal 136 and receives Vip. A base of BP2 204 is coupled to the second terminal 137 and receives Vim. An emitter of BP1 202 is coupled to the second terminal of the first current source 106, the first terminal of the first resistor 128, and the first terminal of the third resistor 132. An emitter of BP2 204 is coupled to the second terminal of the second current source 108, the first terminal of the second resistor 130, and the first terminal of the fourth resistor 134. A collector of BP1 202 is coupled to a first terminal of the fifth resistor 210, the non-inverting input of the fully differential amplifier 209, and the first terminal of the third current source 114. A collector of BP2 204 is coupled to a first terminal of the sixth resistor 212, an inverting input of the fully differential amplifier 209, and the first terminal of the fourth current source 116.

Second terminals of the fifth and sixth resistors 210 and 212 are each coupled to a non-inverting input of the first error amplifier 206. In some examples, resistors 210 and 212 can be described as a first voltage divider. An inverting input of the first error amplifier 206 is coupled to the third input terminal 138 and receives Vintcm_ref. An output of the first error amplifier 206 is coupled to the second terminals of the first and second resistors 128 and 130.

A negative output of the fully differential amplifier 209 is coupled to a second terminal of the third resistor 132 and a first terminal of the seventh resistor 214. A positive output of the fully differential amplifier 209 is coupled to a second terminal of the fourth resistor 134 and a first terminal of the eighth resistor 216. A second terminal of the seventh resistor 214 and a second terminal of the eighth resistor 216 are coupled to a non-inverting input of the second error amplifier 208. In some examples, resistors 214 and 216 can be described as a second voltage divider. An inverting input of the second error amplifier 208 is coupled to the fourth input terminal 140 to receive Vocm_ref. An output of the second error amplifier 208 is coupled to a third input of the fully differential amplifier 209.

As described above, a voltage at node A 142 is Vintp, and a voltage at node B 144 is Vintm. In an example, a resistance of the fifth resistor 210 equals a resistance of the sixth resistor 212, so that an average of Vintp and Vintm is provided to the non-inverting input of the first error amplifier 206. As described above, a voltage at node C 146 is Vop, and a voltage at node D 148 is Vom. In an example, a resistance of the seventh resistor 214 equals a resistance of the eighth resistor 216, so that an average of Vop and Vom is provided to the non-inverting input of the second error amplifier 208.

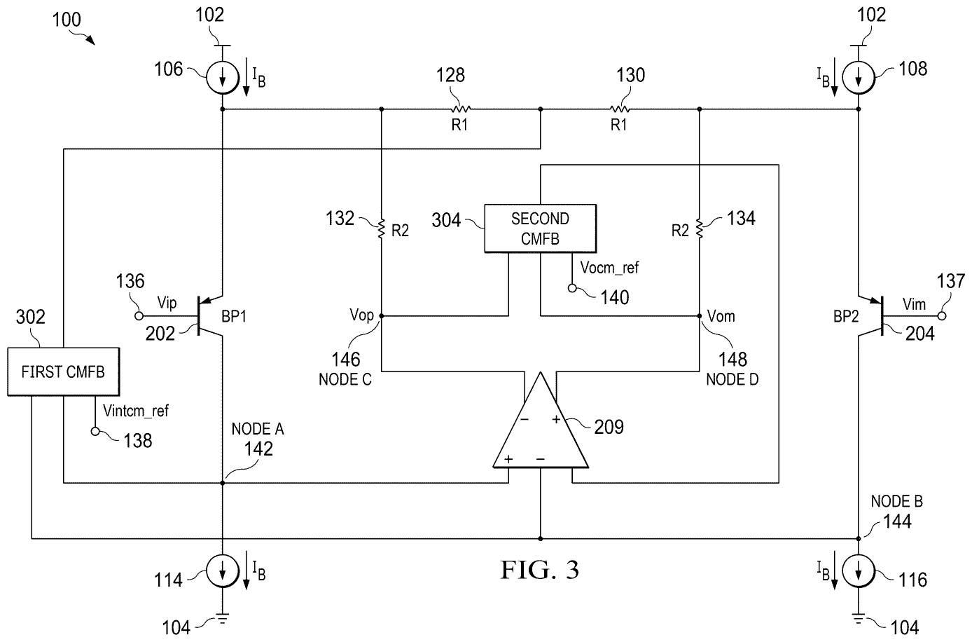

FIG. 3 is another example circuit diagram of the instrumentation amplifier 100 of FIG. 1. The instrumentation amplifier 100 includes a first CMFB 302 and a second CMFB 304. The first CMFB 302 corresponds to the first voltage sensor 118 and the first error amplifier 120, and similarly, provides a feedback signal at its output to control Vintcm. The second CMFB 304 corresponds to the second voltage sensor 122 and the second error amplifier 124, and similarly, provides a feedback signal at its output to control Vocm. In some examples, the first CMFB 302 or the second CMFB 304 includes components other than a voltage sensor and an error amplifier.

A first input of the first CMFB 302 is coupled to the third input terminal 138, which receives Vintcm_ref. A second input of the first CMFB 302 is coupled to node A 142. A third input of the first CMFB 302 is coupled to node node B 144. An output of the first CMFB 302 is coupled to the first terminals of the first and second resistors 128 and 130.

A first input of the second CMFB 304 is coupled to the fourth input terminal 140, which receives Vocm_ref. A second input of the second CMFB 304 is coupled to node C 146. A third input of the second CMFB 304 is coupled to node D 148. An output of the second CMFB 304 is coupled to the third input of the fully differential amplifier 209.

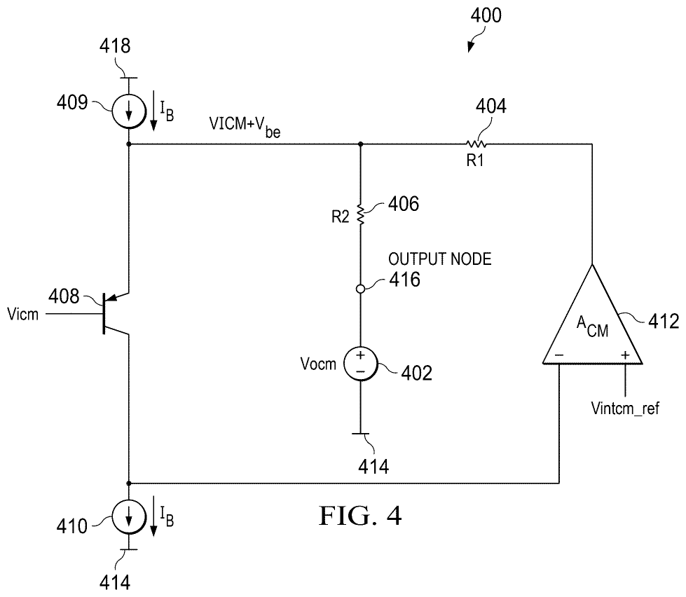

FIG. 4 is a common-mode equivalent circuit diagram 400 of the instrumentation amplifier 100 of FIG. 1. The common-mode equivalent circuit diagram 400 shows the feedback loops that certain signals in the instrumentation amplifier 100 travel. The common-mode equivalent circuit diagram 400 includes a voltage source 402 that provides voltage Vocm (the common-mode output voltage described with respect to FIGS. 1, 2, and 3), a first resistor 404 with resistance R1, a second resistor 406 with resistance R2, a BJT 408, a first current source 409, a second current source 410, and an error amplifier 412. The first and second current sources 409 and 410 each provide an input bias current I_{B}.

A base of the BJT 408 receives Vicm. The collector of the BJT 408 is coupled to a first terminal of the second current source 410 and an inverting input of the error amplifier 412. A second terminal of the second current source 410 is coupled to a ground terminal 414. A non-inverting input of the error amplifier 412 receives Vintcm_ref. An output of the error amplifier 412 is coupled to a first terminal of the first resistor 404.

A negative terminal of the voltage source 402 is coupled to the ground terminal 414. A positive terminal of the voltage source 402 is coupled to a first terminal of the second resistor 406. A second terminal of the first resistor 404 is coupled to a second terminal of the second resistor 406, an emitter of the BJT 408, and a second terminal of the first current source 409. A second terminal of the first current source 409 is coupled to a power supply terminal 418.

In some examples, the instrumentation amplifier 100 can be described as symmetric (consider FIG. 3). In the common-mode equivalent circuit diagram 400, the BJT 408 is the input stage of the circuit. The base of the BJT 408 receives common-mode input voltage Vicm. Accordingly, as further described below, the common-mode equivalent circuit diagram 400 can be described as equivalent to folding the instrumentation amplifier 100 in half about an axis of symmetry (such as down the middle of FIG. 3.). The first resistor 404 corresponds to the first and second resistors 128 and 130, the second resistor 406 corresponds to the third and fourth resistors 132 and 134, the BJT 408 corresponds to BP1 202 and BP2 204, the first current source 409 corresponds to the first and second current sources 106 and 108, and the second current source 410 corresponds to the third and fourth current sources 114 and 116.

The common-mode equivalent circuit diagram 400 models the feedback loops that set Vintcm and Vocm. The error amplifier 412 corresponds to the first CMFB 302. The error amplifier 412 provides a feedback signal responsive to its inputs. A first input of the error amplifier 412 receives Vintcm_ref. A second input of the error amplifier 412 receives a voltage corresponding to a difference between a current provided by the collector of the BJT 408 and I_{B}. A feedback signal provided by the error amplifier 412 is received by the emitter of the BJT 408 via the first resistor 404.

The voltage source 402 corresponds to the second CMFB 304 together with the fully differential amplifier 209, with a difference between the differential inputs of the fully differential amplifier 209 set to zero volts. In this example, the output common-mode voltage of the fully differential amplifier 209 is responsive only to feedback from the second CMFB 304. Accordingly, the voltage source 404 sets the voltage at the output node 416 to Vocm.

As described above, the feedback loop that sets Vintem travels from the output of the error amplifier 412 through a circuit loop back to an input of the error amplifier 412. The feedback loop that sets Vocm travels a completely separate path, corresponding to the voltage source 404 providing voltage Vocm, which sets the voltage Vocm at the output node 416. Accordingly, the feedback loop that sets Vocm is separate and independent from the feedback loop that sets Vintcm. This avoids competing loop timing considerations, enables separately improving the stability of input and output common-mode voltage feedback paths and of the differential gain path, and improves stability and accuracy of the instrumentation amplifier 100.

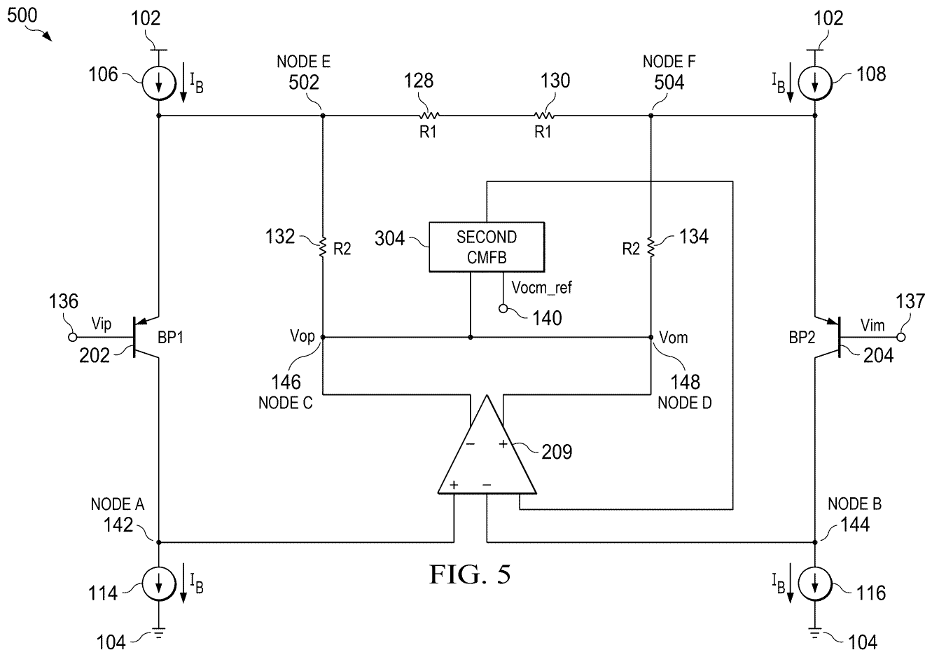

FIG. 5 is a circuit diagram of an instrumentation amplifier 500 similar to the instrumentation amplifier 100 of FIG. 3, without the first CMFB 302. There is a node E 502 between the first resistor 128, the third resistor 132, the first current source 106, and the emitter of BP1 202. There is a node F 504 between the second resistor 130, the fourth resistor 134, the second current source 108, and the emitter of BP2 204.

In some examples, the base-emitter voltage (Vbe) of BP1 202 equals the Vbe of BP2 204 (both will be referred to as Vbe). If the instrumentation amplifier 500 is quiescent (receives no data signal), then Vip equals Vim equals Vicm. In this example, the voltage at node E 502 equals Vicm plus Vbe, and the voltage at node F 504 equals Vicm plus Vbe. If there is an increase in Vicm, then the voltages at nodes E and F 502 and 504 increase. Accordingly, there is an increase in a current (Ix) from node E 502 to node C 146, and from node F 504 to node D 148. If Ix is greater than I_{B}, then the collector current for BP1 202 and BP2 204 goes to zero, and the fully differential amplifier 209 receives zero input.

In the instrumentation amplifier 100, the first CMFB 302 injects current between the first and second resistors 128 and 130. This enables the instrumentation amplifier 100 to avoid input stages 202 and 204 going dry due to variations in Vicm.

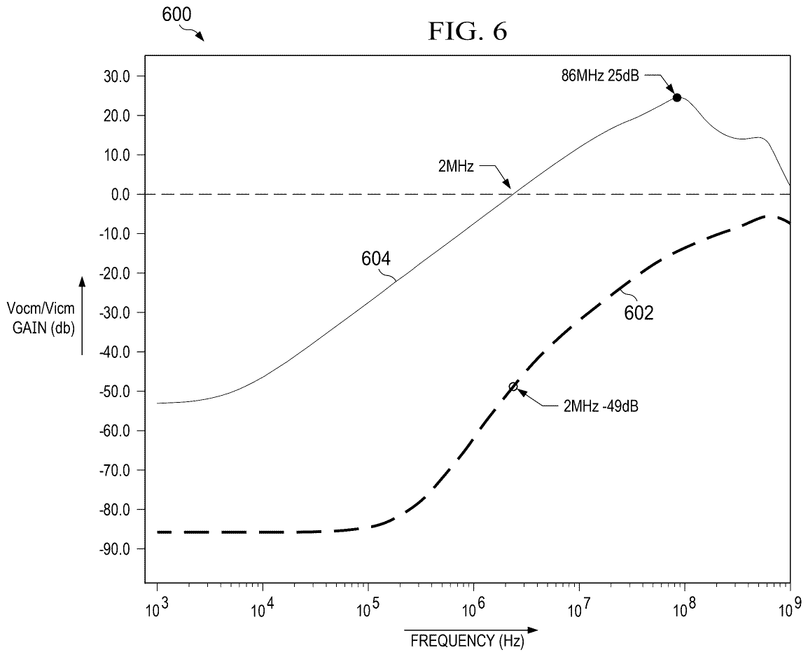

FIG. 6 is a graph 600 of common-mode voltage gain against frequency for the instrumentation amplifier 100 of FIG. 1 and for a second example instrumentation amplifier (not shown). The second instrumentation amplifier has a differential output stage that uses two separate amplifiers to drive the outputs Vop and Vom. Each of these amplifiers respectively has an input coupled to Vintcm_ref to set common-mode voltages (intermediate common-mode voltages) at the respective inputs of the separate amplifiers. A signal path to set these intermediate common-mode voltages is not independent from a feedback signal path to set the differential gain of the second instrumentation amplifier. Accordingly, in the second instrumentation amplifier, common-mode loop stability impacts differential loop stability.

A vertical axis represents common-mode gain, accordingly, change of Vocm with respect to changes in Vicm. In an example, this gain is measured in decibels (dB). A horizontal axis represents input frequency of the instrumentation amplifier (the instrumentation amplifier 100 or the second instrumentation amplifier). In the example, this frequency is measured in Hertz (Hz). A first gain curve 602 corresponds to behavior of the instrumentation amplifier 100. A second gain curve 604 corresponds to behavior of the second instrumentation amplifier.

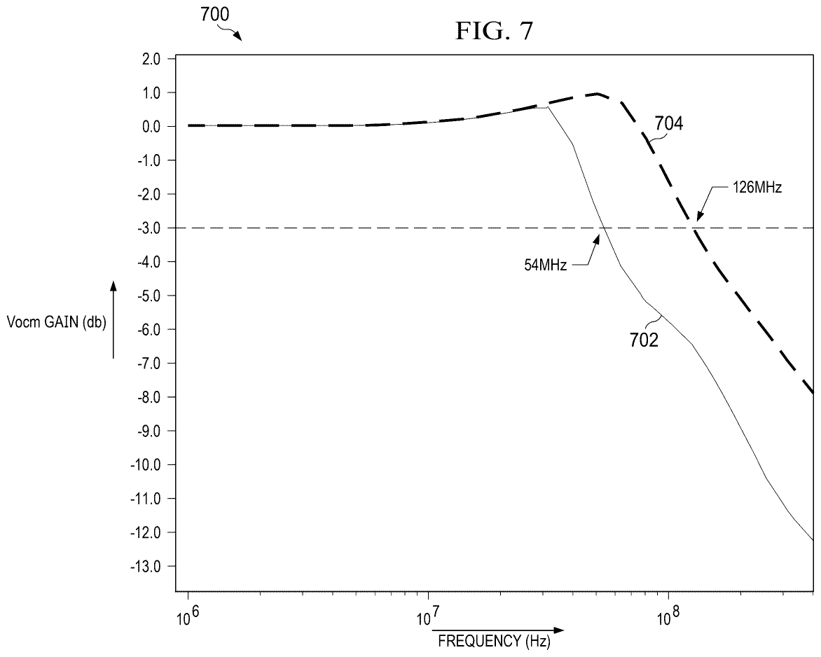

In some examples, as an input frequency of the instrumentation amplifier 100 increases, the gain from Vicm to Vocm increases. Large (such as unity gain, or zero dB) changes in Vocm responsive to changes in Vicm may reduce an available range of output voltages of the instrumentation amplifier. In some examples, this can lead to reduced large-signal bandwidth and increased harmonic distortion, as shown in FIGS. 7 through 10. At 2.4 Mhz, the second gain curve 604 shows unity gain, and the first gain curve 602 shows a gain of about-49 dB, approximately 1/300th of the gain shown by the second gain curve 604. The second gain curve 604 shows that the instrumentation amplifier has a maximum ΔVocm/ΔVicm gain of 24 dB. The first gain curve 602 shows that the instrumentation amplifier 100 has a maximum ΔVocm/ΔVicm gain less than unity gain. Accordingly, use of mutually independent feedback loops for Vintcm and Vocm, and use of a fully-differential amplifier in a corresponding signal path, help to suppress changes in Vocm responsive to changes in device input frequency.

FIG. 7 is a graph 700 of differential gain against frequency for the second instrumentation amplifier described with respect to FIG. 6. A vertical axis represents voltage gain of the instrumentation amplifier. In an example, this gain is measured in dB. A horizontal axis represents input frequency of the second instrumentation amplifier. In the example, this frequency is measured in Hz. The graph 700 shows large signal bandwidth (LSBW) of the second instrumentation amplifier.

A first gain curve 702 corresponds to behavior of the second instrumentation amplifier responsive to a single-ended input. A second gain curve 704 corresponds to behavior of the second instrumentation amplifier responsive to a differential input. The first gain curve 702 falls to −3.0 dB at 54 MHz. The second gain curve 704 falls to −3.0 dB at 125 MHz. Accordingly, for the second instrumentation amplifier, LSBW for single-ended operation is less than half the LSBW for differential operation.

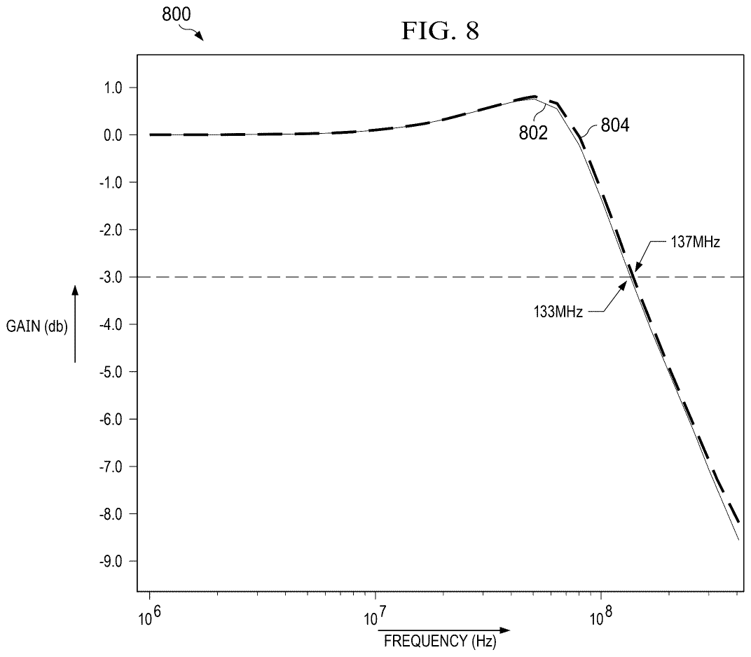

FIG. 8 is a graph 800 of differential gain against frequency for the instrumentation amplifier 100 of FIG. 1. A vertical axis represents voltage gain of the instrumentation amplifier. In an example, this gain is measured in dB. A horizontal axis represents input frequency of the instrumentation amplifier 100. In the example, this frequency is measured in Hz. The graph 800 shows LSBW of the first instrumentation amplifier 100.

A first gain curve 802 corresponds to behavior of the instrumentation amplifier 100 responsive to a single-ended input. A second gain curve 704 corresponds to behavior of the instrumentation amplifier 100 responsive to a differential input. The first gain curve 802 falls to −3.0 dB at 133 MHz. The second gain curve 704 falls to −3.0 dB at 137 MHz. Accordingly, for the instrumentation amplifier 100, LSBW for single-ended operation is approximately the same as the LSBW for differential operation.

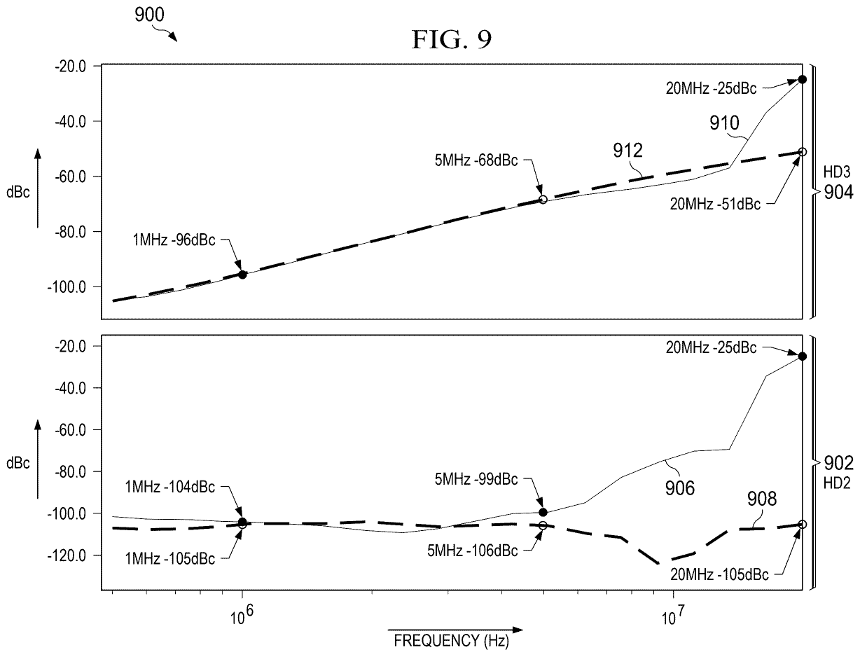

FIG. 9 is a set of graphs 900 of distortion against frequency for different distortion harmonics for the second instrumentation amplifier described with respect to FIG. 6. A first graph 902 shows second harmonic distortion (HD2) against frequency. A vertical axis of the first graph 902 represents decibels relative to the carrier (dBc). A horizontal axis represents input frequency of the second instrumentation amplifier. In the example, this frequency is measured in Hz. A second graph 904 shows third harmonic distortion (HD3) against frequency. A vertical axis of the second graph represents dBc. A horizontal axis represents input frequency of the second instrumentation amplifier.

In the first graph 902, a single-ended signal curve 906 shows HD2 responsive to a single-ended signal. HD2 for a single-ended signal is −104 dBc at 1 MHZ, and −25 dBc at 20 Mhz. A differential signal curve 908 shows HD2 responsive to a differential signal. HD2 for a differential signal is −105 dBc at 1 MHz, and −105 dBc at 20 MHz.

In the second graph 904, a single-ended signal curve 910 shows HD3 responsive to a single-ended signal. HD3 for a single-ended signal is −95 dBc at 1 MHz, and −25 dBc at 20 Mhz. A differential signal curve 912 shows HD3 responsive to a differential signal. HD3 for a differential signal is −95 dBc at 1 MHz, and −51 dBc at 20 MHz.

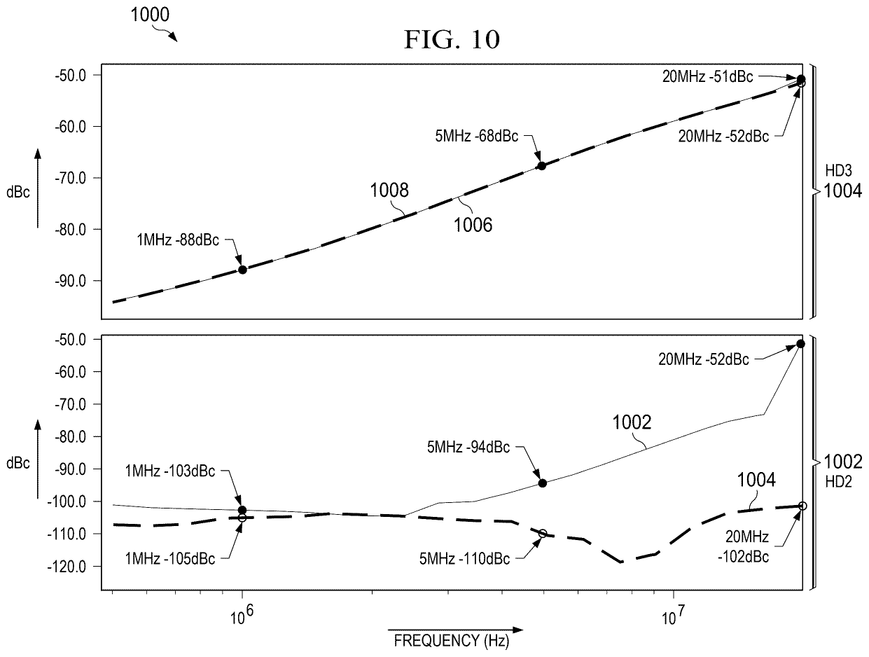

FIG. 10 is a set of graphs 1000 of distortion against frequency for different distortion harmonics for the instrumentation amplifier 100 of FIG. 1. A first graph 1002 shows HD2 against frequency. A vertical axis of the first graph 1002 represents dBc. A horizontal axis represents input frequency of the instrumentation amplifier 100. In the example, this frequency is measured in Hz. A second graph 1004 shows HD3 against frequency. A vertical axis of the second graph represents dBc. A horizontal axis represents input frequency of the instrumentation amplifier 100.

In the first graph 1002, a single-ended signal curve 1006 shows HD2 responsive to a single-ended signal. HD2 for a single-ended signal is −102 dBc at 1 MHz, and −52 dBc at 20 Mhz. A differential signal curve 1008 shows HD2 responsive to a differential signal. HD2 for a differential signal is −105 dBc at 1 MHz, and −102 dBc at 20 MHz.

In the second graph 1004 (HD3), a single-ended signal curve 1010 shows HD3 responsive to a single-ended signal. HD3 for a single-ended signal is −88 dBc at 1 MHz, and −51 dBc at 20 Mhz. A differential signal curve 1012 shows HD3 responsive to a differential signal. HD3 for a differential signal is −88 dBc at 1 MHz, and −52 dBc at 20 MHz. Accordingly, the instrumentation amplifier 100 shows an improvement (lessening) of HD2 and HD3 for single-ended signals at high frequency of over 25 dBc with respect to the second instrumentation amplifier.

In some examples, the first, second, third, and fourth current sources 106, 108, 114, and 116 provide different currents. In some examples, the first resistor 128 has a different resistance from the second resistor 130, and/or the third resistor 132 has a different resistance from the fourth resistor 134.

In some examples, the second error amplifier 208 (or 124) provides a current to the third input of the fully differential amplifier 209 (or 126) to adjust Vocm. In some examples, second error amplifier 208 (or 124) provides a voltage to the third input of the fully differential amplifier 209 (or 126) to adjust Vocm.

In some examples, transistors other than BJTs, such as complimentary metal-oxide-semiconductor (CMOS) transistors, are used in an input stage 110 and/or 112.

In some examples, a capacitor (or other capacitance) replaces each of the fifth resistor 210 and the sixth resistor 212 to perform the first voltage sensor 118 function. In some examples, a capacitor (or other capacitance) is coupled in parallel to each of the fifth resistor 210 and the sixth resistor 212 to perform the first voltage sensor 118 function.

In some examples, a capacitor (or other capacitance) replaces each of the seventh resistor 214 and the eighth resistor 216 to perform the second voltage sensor 122 function. In some examples, a capacitor (or other capacitance) is coupled in parallel to each of the seventh resistor 214 and the eighth resistor 216 to perform the second voltage sensor 122 function.

In some examples, a circuit other than the first voltage sensor 118 and the first error amplifier 120 is used to determine a first common-mode voltage of Vintp and Vintm, and provide a current to a node between the first and second resistors 128 and 130 responsive to a difference between the first common-mode voltage and a first reference voltage.

In some examples, a circuit other than the second voltage sensor 122 and the second error amplifier 124 is used to determine a second common-mode voltage of Vop and Vom, and provide a current to the fully differential amplifier 126 responsive to a difference between the second common-mode voltage and a second reference voltage.

In some examples, processes described herein are implemented using hardware, software, or a combination of hardware and software.

In some examples, ICs described herein may include a processor such as a central processing unit (CPU), a digital signal processor (DSP), or a microcontroller unit (MCU).

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or IC package) and may be adapted to be coupled to at least some of the passive elements and/or the sources to form the described structure either at a time of manufacture or after a time of manufacture, for example, by an end-user and/or a third-party.

The techniques described in this disclosure may also be embodied or encoded in an article of manufacture including a non-transitory computer-readable storage medium. Example non-transitory computer-readable storage media may include random access memory (RAM), read-only memory (ROM), programmable ROM, erasable programmable ROM, electronically erasable programmable ROM, flash memory, a solid-state drive, a hard disk, magnetic media, optical media, or any other computer readable storage devices or tangible computer readable media. The term “non-transitory” may indicate that the storage medium is not embodied in a carrier wave or a propagated signal. In certain examples, a non-transitory storage medium may store data that can, over time, change (e.g., in RAM or cache).

While the use of particular transistors are described herein, other transistors (or equivalent devices) may be used instead with little or no change to the remaining circuitry. For example, a metal-oxide-silicon FET (“MOSFET”) (such as an n-channel MOSFET, nMOSFET, or a p-channel MOSFET, pMOSFET), a bipolar junction transistor (BJT—e.g. NPN or PNP), insulated gate bipolar transistors (IGBTs), and/or junction field effect transistor (JFET) may be used in place of or in conjunction with the devices disclosed herein. The transistors may be depletion mode devices, drain-extended devices, enhancement mode devices, natural transistors or other type of device structure transistors. Furthermore, the devices may be implemented in/over a silicon substrate (Si), a silicon carbide substrate (SiC), a silicon germanium (SiGe) substrate, a gallium nitride substrate (GaN) or a gallium arsenide substrate (GaAs).

Circuits described herein may be reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples may be included in an IC and other elements are external to the IC, in other example embodiments, additional or fewer features may be incorporated into the IC. In addition, some or all of the features illustrated as being external to the IC may be included in the IC and/or some features illustrated as being internal to the IC may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means+/−10 percent of the stated value, or, if the value is zero, a reasonable range of values around zero.

While this disclosure has been described with reference to illustrative embodiments, this description is not limiting. Various modifications and combinations of the illustrative embodiments, as well as other embodiments, will be apparent to persons skilled in the art upon reference to the description.

Modifications are possible in the described examples, and other examples are possible, within the scope of the claims.

What is claimed is:

1. A device comprising:
a first voltage sensor having first and second inputs and an output;
a first error amplifier having first and second inputs and an output, the first input of the first error amplifier coupled to the output of the first voltage sensor;
a second voltage sensor having first and second inputs and an output;
a second error amplifier having first and second inputs and an output, the first input of the second error amplifier coupled to the output of the second voltage sensor;
a fully differential amplifier having first, second, and third inputs and first and second outputs, the first input of the fully differential amplifier coupled to the first input of the first voltage sensor, the second input of the fully differential amplifier coupled to the second input of the first voltage sensor, the third input of the fully differential amplifier coupled to the output of the second error amplifier, the first output of the fully differential amplifier coupled to the first input of the second voltage sensor and the output of the first error amplifier, and the second output of the fully differential amplifier coupled to the second input of the second voltage sensor and the output of the first error amplifier.

2. The device of claim 1, further comprising first, second, third, and fourth resistors each having respective first and second terminals, the first terminal of the first resistor coupled to the first terminal of the third resistor, the first terminal of the second resistor coupled to the first terminal of the fourth resistor, the second terminal of the first resistor coupled to the second terminal of the second resistor and to the output of the first error amplifier, the second terminal of the third resistor coupled to the first input of the second voltage sensor and the first output of the fully differential amplifier, and the second terminal of the fourth resistor coupled to the second input of the second voltage sensor and the second output of the fully differential amplifier.

3. The device of claim 2,
wherein the first and second resistors have a same resistance; and
wherein the third and fourth resistors have a same resistance.

4. The device of claim 1, further comprising first, second, third, and fourth current sources each having respective first and second terminals, the first output of the fully differential amplifier coupled to the first terminal of the first current source, the second output of the fully differential amplifier coupled to the first terminal of the second current source, the first input of the first voltage sensor and the first input of the fully differential amplifier each coupled to the first terminal of the third current source, and the second input of the first voltage sensor and the second input of the fully differential amplifier each coupled to the first terminal of the fourth current source.

5. The device of claim 1, further comprising:
a first input stage having first and second inputs and an output, the first input of the first input stage coupled to the first output of the fully differential amplifier, and the output of the first input stage coupled to the first input of the fully differential amplifier and the first input of the first voltage sensor; and
a second input stage having first and second inputs and an output, the first input of the second input stage coupled to the second output of the fully differential amplifier, and the output of the second input stage coupled to the second input of the fully differential amplifier and the second input of the first voltage sensor.

6. The device of claim 1, further comprising:
a first bipolar junction transistor (BJT) having a base, a collector, and an emitter, the emitter of the first BJT coupled to the first output of the fully differential amplifier, and the collector of the first BJT coupled to the first input of the fully differential amplifier and the first input of the first voltage sensor; and
a second bipolar junction transistor (BJT) having a base, a collector, and an emitter, the emitter of the second BJT coupled to the second output of the fully differential amplifier, and the collector of the second BJT coupled to the second input of the fully differential amplifier and the second input of the first voltage sensor.

7. The device of claim 1, wherein the second voltage sensor includes a first resistor and a second resistor each having respective first and second terminals, the first terminal of the first resistor coupled to the first input of the second voltage sensor, the first terminal of the second resistor coupled to the second input of the second voltage sensor, and the second terminals of the first and second resistors coupled to the output of the second voltage sensor.

8. A device comprising:
a first common mode feedback (CMFB) circuit having first, second, and third inputs and an output;
a second CMFB circuit having first, second, and third inputs and an output;
a fully differential amplifier having first, second, and third inputs and first and second outputs, the first input of the fully differential amplifier coupled to the first input of the first CMFB circuit, the second input of the fully differential amplifier coupled to the second input of the first CMFB circuit, the third input of the fully differential amplifier coupled to the output of the second CMFB circuit, the first output of the fully differential amplifier coupled to the first input of the second CMFB circuit and the output of the first CMFB circuit, and the second output of the fully differential amplifier coupled to the second input of the second CMFB circuit and the output of the first CMFB circuit.

9. The device of claim 8, wherein the first CMFB circuit includes:
a voltage sensor having a first input, a second input, and an output, the first input of the voltage sensor coupled to the first input of the first CMFB circuit, and the second input of the voltage sensor coupled to the second input of the first CMFB circuit; and
an error amplifier having a first input, a second input, and an output, the first input of the error amplifier coupled to the output of the voltage sensor, and the output of the error amplifier coupled to the output of the first CMFB circuit.

10. The device of claim 9, wherein the first voltage sensor includes a first resistor and a second resistor each having respective first and second terminals, the first terminal of the first resistor coupled to the first input of the first voltage sensor, the first terminal of the second resistor coupled to the second input of the first voltage sensor, and the second terminals of the first and second resistors coupled to the output of the first voltage sensor.

11. The device of claim 8, wherein the second CMFB circuit includes:
a voltage sensor having a first input, a second input, and an output, the first input of the voltage sensor coupled to the first input of the second CMFB circuit, and the second input of the voltage sensor coupled to the second input of the second CMFB circuit; and
an error amplifier having a first input, a second input, and an output, the first input of the error amplifier coupled to the output of the voltage sensor, and the output of the error amplifier coupled to the output of the second CMFB circuit.

12. The device of claim 11, wherein the second voltage sensor includes a first resistor and a second resistor each having respective first and second terminals, the first terminal of the first resistor coupled to the first input of the second voltage sensor, the first terminal of the second resistor coupled to the second input of the second voltage sensor, and the second terminals of the first and second resistors coupled to the output of the second voltage sensor.

13. The device of claim 8, further comprising first, second, third, and fourth resistors each having respective first and second terminals, the first terminal of the first resistor coupled to the first terminal of the third resistor, the first terminal of the second resistor coupled to the first terminal of the fourth resistor, the second terminal of the first resistor coupled to the second terminal of the second resistor and to the output of the first CMFB circuit, the second terminal of the third resistor coupled to the first input of the second CMFB circuit and the first output of the fully differential amplifier, and the second terminal of the fourth resistor coupled to the second input of the second CMFB circuit and the second output of the fully differential amplifier.

14. The device of claim 13,
wherein the first and second resistors have a same resistance; and
wherein the third and fourth resistors have a same resistance.

15. The device of claim 8, further comprising first, second, third, and fourth current sources each having respective first and second terminals, the first output of the fully differential amplifier coupled to the first terminal of the first current source, the second output of the fully differential amplifier coupled to the first terminal of the second current source, the first input of the first CMFB circuit and the first input of the fully differential amplifier each coupled to the first terminal of the third current source, and the second input of the first CMFB circuit and the second input of the fully differential amplifier each coupled to the first terminal of the fourth current source.

16. The device of claim 8, further comprising:
a first input stage having first and second inputs and an output, the first input of the first input stage coupled to the first output of the fully differential amplifier, and the output of the first input stage coupled to the first input of the fully differential amplifier and the first input of the first CMFB circuit; and
a second input stage having first and second inputs and an output, the first input of the second input stage coupled to the second output of the fully differential amplifier, and the output of the second input stage coupled to the second input of the fully differential amplifier and the second input of the first CMFB circuit.

17. The device of claim 8, further comprising:
a first bipolar junction transistor (BJT) having a base, a collector, and an emitter, the emitter of the first BJT coupled to the first output of the fully differential amplifier, and the collector of the first BJT coupled to the first input of the fully differential amplifier and the first input of the first CMFB circuit; and
a second bipolar junction transistor (BJT) having a base, a collector, and an emitter, the emitter of the second BJT coupled to the second output of the fully differential amplifier, and the collector of the second BJT coupled to the second input of the fully differential amplifier and the second input of the first CMFB circuit.

18. A device comprising:
a first input stage having first and second inputs and an output;
a second input stage having first and second inputs and an output;
a first common mode feedback (CMFB) circuit having first and second inputs and an output;
a second CMFB circuit having first and second inputs and an output;
a fully differential amplifier having first, second, and third inputs and first and second outputs, the output of the first input stage coupled to the first input of the fully differential amplifier and the first input of the first CMFB circuit, the output of the second input stage coupled to the second input of the fully differential amplifier and the second input of the first CMFB circuit, the third input of the fully differential amplifier coupled to the output of the second CMFB circuit, the first output of the fully differential amplifier coupled to the first input of the first input stage, the first input of the second CMFB circuit, and the output of the first CMFB circuit, and the second output of the fully differential amplifier coupled to the first input of the second input stage, the second input of the second CMFB circuit, and the output of the first CMFB circuit.

19. The device of claim 18, further comprising first, second, third, and fourth resistors each having respective first and second terminals, the first terminal of the first resistor coupled to the first terminal of the third resistor, the first terminal of the second resistor coupled to the first terminal of the fourth resistor, the second terminal of the first resistor coupled to the second terminal of the second resistor and to the output of the first error amplifier, the second terminal of the third resistor coupled to the first input of the second voltage sensor and the first output of the fully differential amplifier, and the second terminal of the fourth resistor coupled to the second input of the second voltage sensor and the second output of the fully differential amplifier.

20. The device of claim 18, wherein the first and second CMFB circuits each respectively include:
a voltage sensor having a first input, a second input, and an output, the first input of the voltage sensor coupled to the first input of the respective CMFB circuit, and the second input of the voltage sensor coupled to the second input of the respective CMFB circuit; and
an error amplifier having a first input, a second input, and an output, the first input of the error amplifier coupled to the output of the voltage sensor, and the output of the error amplifier coupled to the output of the respective CMFB circuit.
